(19) United States
(12) Patent Application Publication
(10) Pub. No.: US 2026/0186052 A1
(43) Pub. Date: Jul. 2, 2026

(54) FAULT INJECTION AND DETERMINISTIC REPAIR FOR DEBUG OF PACKAGED SEMICONDUCTOR DIES

(71) Applicant: Intel Corporation, Santa Clara, CA (US)

(72) Inventors: Rakesh KANDULA, Bangalore (IN); Dror ZILBERMAN, Kiryat Ono (IL); R Selvakumar RAJAGOPAL, Tapah (MY); Mahesh Deepak BENDRE, Bengaluru (IN); Idan SHALEV, Kiryat Motzkin (IL)

(21) Appl. No.: 19/003,435

(22) Filed: Dec. 27, 2024

(51) Int. Cl. G01R 31/3183; G01R 31/317

(52) U.S. Cl. CPC G01R 31/3183; G01R 31/31724; G01R 31/31727

(57) ABSTRACT

Devices and methods for identifying failures in multichip packages are provided. Additionally, devices and methods for repairing identified failures in multichip packages are provided.

### FIELD

Descriptions are generally related to semiconductor devices, and more particular descriptions are related to testing multichip packages that can include stacked dies, high density interconnects, interposers, and systems on a chip.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor devices comprising a system on a chip (SOC) can integrate what are referred to as partitions or blocks into a monolithic die. The SOC can include, for example, a central processing unit (CPU), a graphics processing unit (GPU), an image processing unit (IPU), a neural processing unit (NPU), a bus interface unit (BIU), and/or a data streaming accelerator (DSA). As a result, die size has increased and resulted in significant manufacturing cost implications. Package-level integration can reduce some of the negative manufacturing cost implications of SOC integration. Various package motifs are possible, such as, for example, 2D planar multichip packages (MCPs), 3D packages (for example, 2 or more dies on a base die) or other types stacked and/or side-by-side MCPs. Multi-chip packages can provide a small form-factor and high density of dies and die interconnects having small pitches. The shorter and smaller the interconnect lines, the smaller the parasitic capacitance and latencies, which can lead to superior performance in MCPs.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 provides an example of a multichip package (MCP) assembly.

FIG. 2 shows transmit circuitry that can be part of the circuitry of a semiconductor die.

FIG. 3 illustrates receive circuitry that can be part of the circuitry of a semiconductor die.

FIG. 4 shows a method for testing semiconductor devices that includes injecting an error from a transmitting die to a receiving die.

FIG. 5 further illustrates a method for testing semiconductor devices that includes injecting an error from a transmitting die to a receiving die.

FIG. 6 illustrates error injection mux circuitry.

FIG. 7 provides a method of performing a deterministic repair on a signal path between a transmitting die and a receiving die.

FIG. 8 shows a method for validating the operation of a multichip package (MCP) assembly.

FIG. 9 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Physical operations can be performed by semiconductor processing and/or testing equipment, including computer systems that run testing protocols and operate aspects of testing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, lithography, probing, material deposition (for example, chemical vapor deposition, atomic layer deposition, physical vapor deposition, electrodeposition, and/or sputtering), chemical mechanical polishing (CMP), and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or through-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass layers.

In further examples of a package substrate core, the substrate core is a glass core comprising one or more solid amorphous glass layers. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23 % silicon, at least 26 % oxygen by weight. In further examples, the glass package substrate core comprises at least 23 % silicon, at least 26 % oxygen, and at least 5 % aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

In a MCP, the connectivity between the top dies can be done through a base die, using interface ports (one on each of the top dies). This type of connectivity can be called D2D (Die-to-Die) interconnectivity. The D2D port can consist of, any number of bundles. In this example, the D2D port consists of 48 bundles, connected to different partitioned units in the top die, and each bundle can have, for example, 10-57 lanes and 1-2 redundant lanes. Any number of lanes can be used. Redundant lanes can be used to replace lanes in which connectivity is damaged, through a process of repair by fusing. The integrity of the connectivity of each lane can be tested by functional built-in self-test (FBIST) circuits in which the two sides of the top dies can act in Tx/Rx (signal transmit/receive) mode.

The attachment of the top die(s) onto a base die can be associated with process yield challenges, since the IO (input output) micro bump pitch is increasingly reduced for interconnects formed during assembly processes. Failure modes during interconnect formation (e.g., bump bonding technologies) include hard defects such as opens and shorts formed through, for example, misalignments. Hard defects can be randomly placed. Failure modes for packaged dies also include systematic failures. Systematic failure modes can occur from design marginality discovered under PVT (process, voltage, temperature) variations and can be, for example, related to process variation of lithographic critical dimensions (CDs) or implant profiles on a wafer's edge, among other things.

A built-in self-test IC controller for MCPs can comprise the following registers that are programmable according to Joint Action Test Group (JTAG) Institute of Electrical and Electronics Engineers (IEEE 1149.1) standard protocol.
a) Failing lane registers: A register width is equal to Log2 (total number of lanes). There can be 3 failing lane registers:
   failing lane 1 register,
   failing lane 2 register, and
   failing lane 3 register.
These registers can record up to 3 failing lanes. There can 2 repair lanes. The third lane can be dedicated to providing additional failure analysis data.
For example, if there are 100 lanes, the width of the register is 7. If lane 10, lane 27, and lane 31 are failing, then:
   the failing lane1 register records 10,
   the failing lane2 register records 27, and
   the failing lane3 register records 31.
b) Per Lane Error Register: This register is as wide as the number of lanes. This register records per lane error information and this register is set to 1 by the hardware if there is a lane failure.
For example, if there are 10 lanes, the width of the register is 10. If lane 5 and lane 7 are failing then the register bit 5 and register bit 7 records 1: 10′b0001010000.
c) Error Injection Register: This register is as wide as number of lanes. If a particular bit is set to 1 by the user, the corresponding lane can be fault injected.
For example, if there are 10 lanes, the width of this register is 10. If the user intends to inject artifact error into lane 4, then the bit 4 is set to 1 by the user.

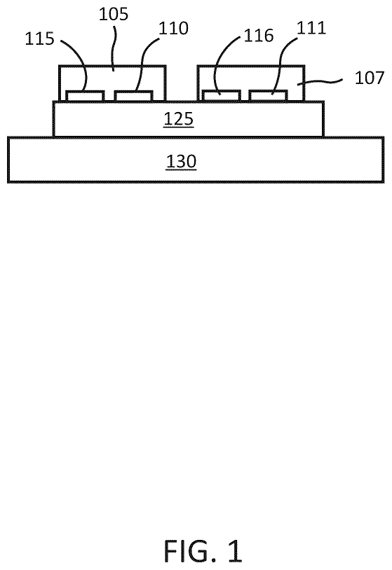

FIG. 1 provides an example of a multichip package. The MCP includes a first semiconductor die 105 and a second semiconductor die 107. The first semiconductor die 105 includes transmit circuitry 115 and receive circuitry 110 and the second semiconductor die 107 includes transmit circuitry 116 and receive circuitry 111. The first semiconductor die 105 and the second semiconductor die 107 are electrically coupled to a third semiconductor die 125. The electrical coupling can be called die-to-die (D2D) coupling. A D2D port can, for example, consist of 48 bundles, connected to different partitioned units in the first die 105, and each bundle can have 10-57 lanes and 1-2 redundant lanes (to replace broken connectivity lanes through a REPAIR function by fusing). In general, bundle, partition, or cluster can be used interchangeably. A partition can refer to the division of a digital circuit design into smaller, more manageable sections or blocks based on functionality, hierarchy, or other design criteria. For example, a compute digital circuitry could be partitioned into Instruction Fetch Unit, Instruction Decode Unit, Execution Unit, Cache Memory (L1, L2). The integrity of the connectivity of each lane can be tested by a FBIST machine in which the two sides of the top dies act in mode of Tx/Rx (transmit/receive). The first semiconductor die 105 and second semiconductor die 107 can be attached to the third semiconductor die 125 through IO micro bumps that have increasingly smaller pitches as technology nodes scale down. The base semiconductor die 125 is electrically connected to a package substrate 130.

In a cluster there could be hundreds of transmit circuitry 115 and 116 units and hundreds of receive circuitry 110 and 111 units. A typical cluster can contain as many as 500 transmit circuitry units and 500 receive circuitry units or more. The number of transmit units can be equal to the number of receive units, both of which can be the same as the number of signals crossing a semiconductor die. The transmit units in a cluster can be controlled by single transmit BIST controller and receive units in a cluster can be controlled by a single receive BIST controller. Transmit units and receive units can include a) Functional Flop, b) Functional Path to be tested, and c) Testing Circuits.

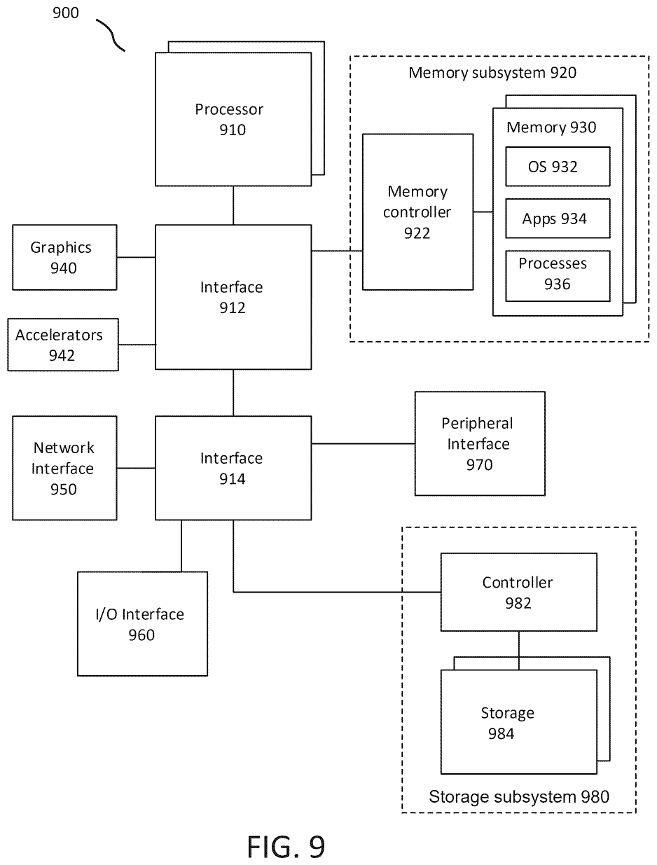

The semiconductor dies 105, 107, and 125 can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), three-dimensional integrated circuits (3D IC), interposers, HBM, and/or other memory devices. The semiconductor chips can be any of the chips, for example, described herein with respect to FIG. 9. For example, the first semiconductor die 105 can be a compute chip, the second semiconductor die 107 can be a SOC chip, and the third semiconductor die 125 can be a 3D IC or an active interposer comprising circuitry. The semiconductor chip packages described herein generally can be part of various larger package structures and configurations and the foregoing example is not meant to limit the types of assemblies that are possible.

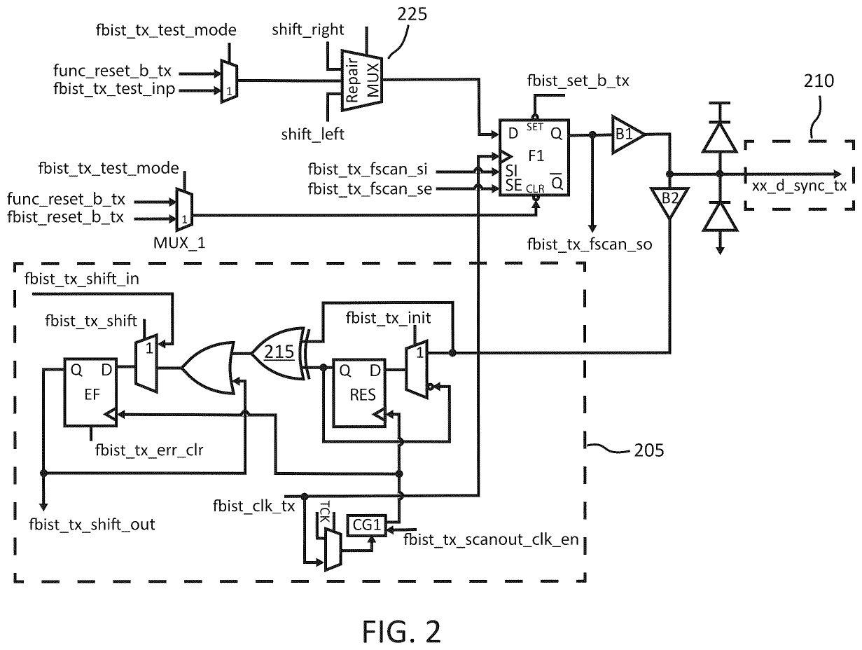

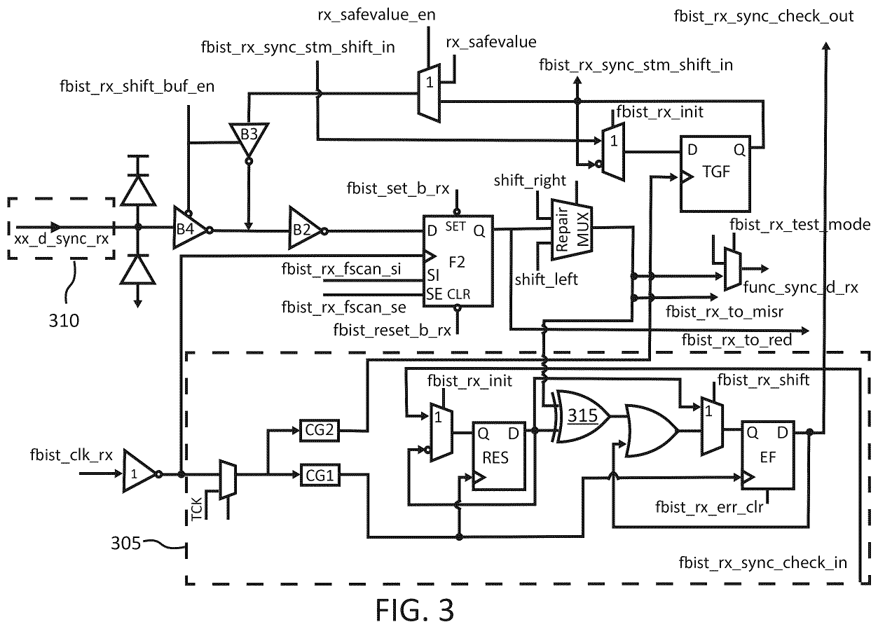

FIG. 2 provides an example of a transmit circuit unit which can be, for example, the transmit circuitry 115 or 116 of FIG. 1. In FIG. 2, F1 is a functional flop. Test circuity is demarcated by a first dashed line 205. A functional path to be tested can be F1->B1->B2. A second dashed line box demarcates a signal IO lane 210 to, for example, a lane between a first semiconductor die and a second semiconductor die. In FIG. 3, a dashed line box 305 demarcates a signal IO lane 310 that could, for example, be electrically coupled to the signal IO lane 210. The first semiconductor die can be the semiconductor die 105, the second semiconductor die can be the semiconductor die 107, and the signal IO lane can traverse a third semiconductor die, such as semiconductor die 125 of FIG. 1. The circuitry CG1 is clock gating circuitry.

FIG. 3 provides an example of a receive circuit unit which can be, for example, the receive circuitry 110 or 111 of FIG. 1. In FIG. 3, F2 is a functional flop. Test circuity is demarcated by a first dashed line 305. Test circuitry can also include the block labeled TGF. The circuitry CG1 and CG2 are clock gating circuitry. A functional path to be tested can include B4->B2.

The F1 and F2 functional flops can be part of the functional logic to be tested. The functional flops F1 and F2, are run on a muxed clock between functional clock and slow test clock. The clock to the F1 and F2 flops is controlled by clock gating cell CG1. The input clock to the clock gate CG1 is a muxed clock between a slow-speed test clock and a full speed functional clock. The clock gating enable and the clock select are generated by the finite state machine (FSM) that is internal to the TX and RX circuits.

The functional path crossing is a crossing through a 3D IC or through link between F1 in a transmitting die and F2 on a receiving die. The crossing can include: F1 (on Tx Die)->B1 (on Tx Die)->B4 (on Rx die)->B2 (On Rx die)->F2 (on Rx die).

In FIG. 2, a testing circuit can comprise: a RES flop, a comparator, and an EF flop. RES flop is the result generating flop. The RES flop can generate a toggle pattern and compare against the test_input coming through the F1 flop. The clock to the RES flop is controlled by clock gate CG1. Test input is generated by test controller and is also a toggle pattern. Test_input toggle pattern traverses through F1. The RES flop on TX circuits can be used for sort testing, i.e., testing before TX die is packaged with a RX die. The RES flop on RX circuits can be used for both sort (die-level) and class (packaged die) testing.

The comparator 215 can be an XOR gate for which inputs are RES output and F1 output through B1 (in the functional path of the TX circuitry). If, for example, the two inputs of XOR gate do not match, its output is 1. The comparator 215 in the TX circuitry can be used for sort testing, i.e., testing before TX die is packaged with a RX die. The comparator 315 in the RX circuitry can be used for both sort (die-level) and class (packaged die) testing.

The EF flop is an error flop. If the XOR comparison fails, the error is logged as 1 into EF flop, which is sticky. The clock to the EF flop is controlled by clock gate CG1. The EF flop can be read out using chain fbist_rx_sync_check_in-->fbist_rx_sync_check_out in FIG. 3 on receive side and using chain fbist_tx_shift_in-->fbist_tx_shift_out in FIG. 2 on transmit side. EF flop in the TX circuitry can be used for sort testing. The EF flop in the RX circuitry can be used for both sort (die-level) and class (packaged die) testing.

The FBIST chain stitches RES-EF flops of the lanes, RES-EF. This is used to read the EF flop for lane failure analysis. For example, if there are 10 lanes and EF flop is set to 1 for 5^{th} lane, then 5^{th} lane has failed.

An example test for links can involve the following stages: 1) initialization, 2) clock switch1, 3) application stage, 4) clock switch2, and 5) EF readout. Initialization can involve a) initializing F2 and RES to the same value and b) switching to the slower clock. Clock switch1 can involve a) switching to a faster clock for the application stage, b) shutting off the clocks before the clock switch happens, and 3) switching to either faster functional clock or slower test clock. The application stage can involve a) running the toggle pattern for 64 clocks or a programmable number of clocks, b) testing for defects from F1 through B1 through B4 through B2 through F2, and c) functional clocks CG1 and CG2 are ungated deterministically. The clock switch2 can involve a) switching to a slower clock for the EF chain read out, b) shutting off the clocks before the clock switch happens, and c) slowing the test clock. The EF read out can involve a) reading out the EF flops to detect failed lanes, b) logging lane failures to user readable registers, and c) slowing the test clock.

The initialization stage can place F2 and RES flop on the receive circuitry (Rx die) at the same value before testing starts in the application stage. F2 is initialized through test_input injected by FBIST controller on the transmit circuitry (Tx die). RES is initialized through the FBIST chain (Using fbist_rx_sync_check_in-->fbist_rx_sync_check_out in FIG. 3). The clock to both F2 and RES are controlled by clock gate CG1 and CG2 respectively, whose input is a muxed clock.

For clock switch1, the clocks are turned off to avoid unwanted glitches and then switched to an intended clock (either slow clock or fast clock depending upon the test stage). The clocks are then ungated, so that the clocks out of the mux will come out as clean (without glitches). In the Clock Switch1 stage, the clock is switched to a faster functional clock on RES and EF flops before entering the application stage.

In the application stage, once the F2 and RES flop on the RX circuits (RX die, or “RX”) are initialized to the same value, the toggling pattern is run through test_input from the FBIST controller on TX circuits (TX die). Because RES on RX is already a toggling flop, RES on RX will continue to run the toggling pattern. CG1 and CG2 on RX are ungated for a pre-determined number of clocks.

For clock switch2, the clocks are shut down to avoid unwanted glitches, switched, and ungated, so that the clocks out of the mux will come out as clean (without glitches). The clock is switched from fast clock to slow clock on RES and EF flops before we go into an EF readout stage. EF readout stage is performed on a slow clock.

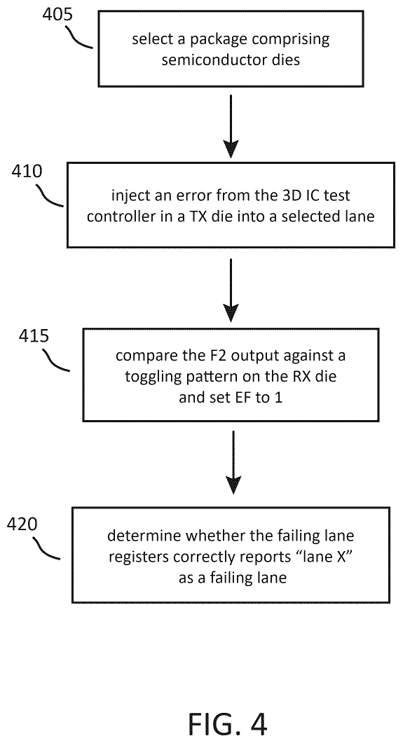

FIG. 4 diagrams a method for testing a semiconductor device, such as a MCP. The MCP can be a 3D IC for example. A semiconductor package comprising dies is selected for testing (405). The semiconductor package can be one that has passed prior tests and/or is believed to be defect free. The package can comprise a first die that is selected to be a signal transmitting die (TX die) and a second die that is selected to be a signal receiving die (RX die). The package can also comprise a third die, such as an interposer or smart interposer through which the signal will pass. Based on the programming set by user through JTAG in the register that is selected to be the error injection register, the MCP test controller in the TX die injects a 0 on a selected lane (410). The 0 traverses the TX die and reaches F2, the functional flop, on the RX die. On the RX die, the F2 output, which is 0, is compared against a toggling pattern on the RX die, and EF is set to 1 (415). If the failing lane registers correctly report lane X as the failing lane, then the reporting mechanism and the logic are working correctly for lane (420). If the failing lane registers do not correctly report lane X as the failing lane, then there is an issue in the error reporting mechanism for lane X (420). The elements of the method shown in FIG. 4 can be repeated for as many as all the lanes. The method of FIG. 4 allows the determination of whether the error report mechanisms, logic implementations, and timing paths are working correctly with respect to fault injection. If a part is failing, it can be known that the failure is not because of an issue in an error report mechanism or the logic implemented in the semiconductor die. In this example, a 0 was injected, however the a 1 could also have been injected.

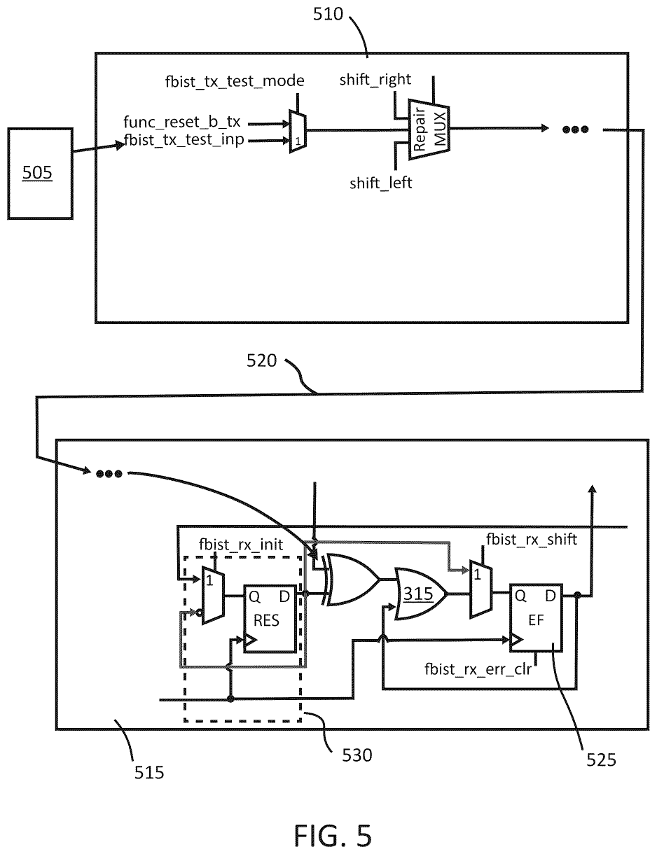

FIG. 5 further illustrates a method for testing a semiconductor device, such as a MCP. A JTAG programmable register that selects a MCP lane to inject an artifact fault is defined in the transmitting die. An MCP test controller 505 in the transmitting die can inject a 0 into the transmit circuitry 510. The transmit circuitry 510 is electrically coupled to a receiving die's receive circuitry 515 through interconnect 520. The transmit circuitry 510 and the receive circuitry 515 (from FIGS. 2 and 3, respectively) are only partially reproduced in FIG. 5 for clarity. The per lane error register 525 (EF) can be as wide as the number of lanes. The per lane error register 525 records per lane error information, and is set to 1 by the hardware if there is a lane failure. For example, if there are 10 lanes, the width of the register is 10 and if lane 5 and lane 7 are failing then per lane error register 525 bits 5 and 7 record a 1, resulting in register values: 10′b0001010000. The toggling circuit 530 creates a “101010 . . . ” pattern. The comparator 315 can detect gate output mismatches.

The error injection register can be as wide as the number of lanes. If a particular bit is set to 1 by the user, the corresponding lane is fault injected. For example, if there are 10 lanes, the width of this register is 10 and if user intends to inject artifact error into lane 4, then the bit 4 is set to 1 by the user.

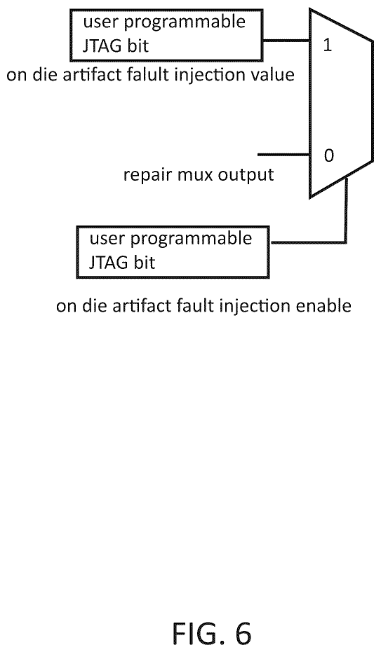

In an additional method, an error injection mux can be placed after the repair mux 225 of FIG. 2. FIG. 6 illustrates an error injection mux that can be used in the transmit circuitry of a transmitting die of a MCP. The error injection mux select line comes from a user programmable JTAG register bit. When the select line is 1, the error injection is enabled and the mux output will be equal to the input from error injection value user programmable bit. The error injection value user programmable bit can be set to 1 or 0 based on selecting to mimic stuck at 0 or stuck at 1 fault. In this additional method, an error can be injected on all the lanes at one time, rather than injecting errors serially as in the methods of FIGS. 4-5. After error injection, the reporting mechanism is checked for correctness in both methods.

In the methods of FIGS. 4-6 , an artifact (error) having a random pattern can be also be injected rather than an artifact having a constant value. Additionally, a random pattern can be driven to inject artifact at-speed faults. For example, a pattern of 11110000 can be injected.

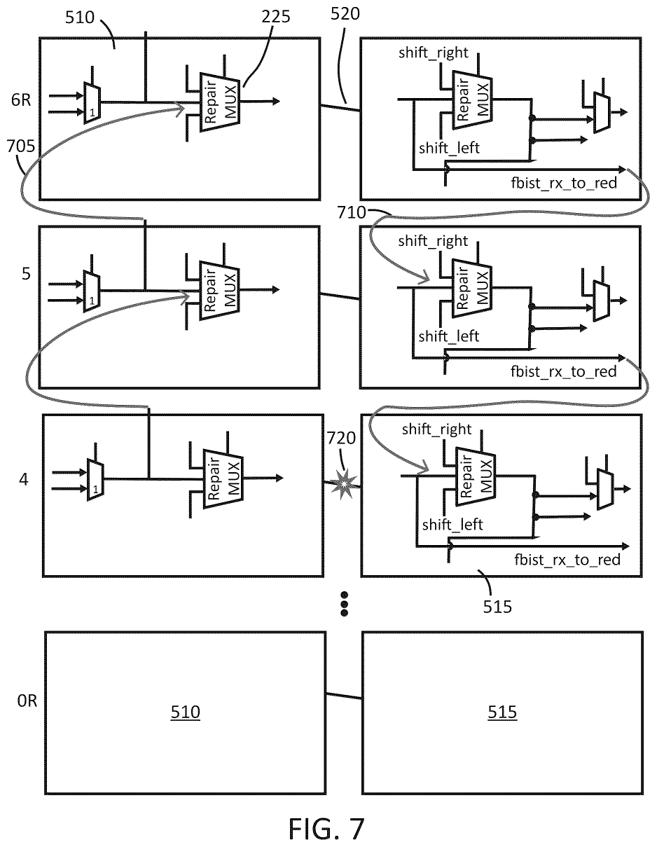

FIG. 7 provides a method of performing a deterministic repair in a MCP. Lane 0 and lane 6 are marked as lane 0R and lane 6R, the R indicating that they are repair lanes or redundant lanes. Lane 1 to lane 5 are functional lanes (not all lanes are shown). On functional lane 4, using, for example, a method described herein (e.g., as shown and described herein with respect to FIGS. 4-6) , an error has been uncovered. The error in the interconnect 520 is illustrated as star 720. The transmit circuitry 510 is electrically coupled to a receiving die's receive circuitry 515 through interconnect 520. The transmit circuitry 510 and the receive circuitry 515 (from FIGS. 2 and 3, respectively) are only partially reproduced in FIG. 5 for clarity. Repair paths 705 and 710 show a signal path repair that bypasses lane 4. On the transmitting die, after repair, data on lane 4 now gets re-routed to lane 5. Similarly, data on lane 5 on the transmitting die now gets re-routed to through lane 6R. The repaired paths can exist for all lanes on the transmit die. On the receive side lane 6R gets re-routed through lane 5. Similarly, lane 5 gets re-routed through lane 4. The repaired paths exist for all lanes on the receive die as well.

Repair paths 705 and 710 can create a longer timing path. If the repair paths 705 and 710 pass test, then the repair on lane 4 is repaired. Potential repair paths can exist in design and in silicon for all lanes on both transmitting dies and receiving dies. For ease of explanation, repair paths are shown only on lane 4 in FIG. 7. The same process can be repeated for additional lanes in a MCP.

Other circuit designs are also possible that can perform the functions described herein.

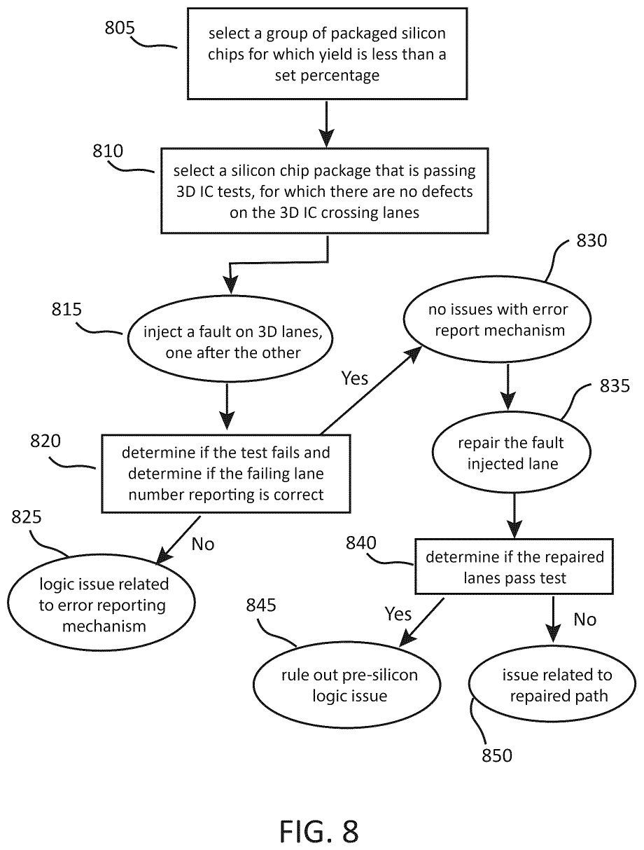

FIG. 8 describes a method for testing a semiconductor package assembly comprising multiple semiconductor dies. A batch or group of MCP assemblies is selected because the manufacturing yield is less than a set percentage (e.g., less than 90%) (805). From this batch or group, a MCP is selected that does not have defects on the 3D IC crossing lanes (810) for further testing. It is then possible to check whether the error report mechanism, logic implementation, and timing paths are working correctly or not with respect to fault injection. It is then possible to know a part is failing not because of issue in the error report mechanism or silicon logic. A fault is injected on the 3D IC crossing lanes (815). The fault can be injected, for example, according to the methods of FIGS. 4-6 , and the faults can be injected one after the other or in parallel. A determination is made as to whether the test fails or not and if a failing lane is discovered, determine if the failing lane number reporting is correct (820). If the test does not fail, a logic issue related to the reporting mechanism exists (825). If the test indicates a failure, then the error reporting mechanism passes the test (830). The failing lane can be repaired (835), using, for example, the shown in and described herein with respect to FIG. 7. Determine if the repaired lane passes test (840). If the repaired lane passes test, a pre-silicon logic issue can be ruled out (845). The issue can be related to manufacturing processes, defects, and/or the manufacturing tools. If the repaired lane does not pass the test, the issue is related to the repaired path (850).

FIG. 9 depicts an example computing system. The computing system can be a system used for running equipment in a semiconductor fabrication plant. For example, instructions for operating semiconductor testing systems, or for performing one or more aspects of the process described herein can be stored and/or run on the computing system. A computing system 900 can include more, different, or fewer features than the ones described with respect to FIG. 9.

Computing system 900 includes processor 910, which provides processing, operation management, and execution of instructions for system 900. Processor 910 can include any type of microprocessor, CPU (central processing unit), GPU (graphics processing unit), processing core, or other processing hardware to provide processing for system 900, or a combination of processors or processing cores. Processor 910 controls the overall operation of system 900, and can be or include, one or more programmable general-purpose or special-purpose microprocessors, DSPs, programmable controllers, ASICs, programmable logic devices (PLDs), or the like, or a combination of such devices.

In one example, system 900 includes interface 912 coupled to processor 910, which can represent a higher speed interface or a high throughput interface for system components needing higher bandwidth connections, such as memory subsystem 920 or graphics interface components 940, and/or accelerators 942. Interface 912 represents an interface circuit, which can be a standalone component or integrated onto a processor die. Where present, graphics interface 940 interfaces to graphics components for providing a visual display to a user of system 900. In one example, the display can include a touchscreen display.

Accelerators 942 can be a fixed function or programmable offload engine that can be accessed or used by a processor 910. For example, an accelerator among accelerators 942 can provide data compression (DC) capability, cryptography services such as public key encryption (PKE), cipher, hash/authentication capabilities, decryption, or other capabilities or services. In some cases, accelerators 942 can be integrated into a CPU socket (e.g., a connector to a motherboard (or circuit board, printed circuit board, mainboard, system board, or logic board) that includes a CPU and provides an electrical interface with the CPU). For example, accelerators 942 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 942 can provide multiple neural networks, CPUs, processor cores, general purpose graphics processing units, or graphics processing units can be made available for use by artificial intelligence (AI) or machine learning (ML) models.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 930 stores and hosts, among other things, operating system (OS) 932 that provides a software platform for execution of instructions in system 900, and stores and hosts applications 934 and processes 936. In one example, memory subsystem 920 includes memory controller 922, which is a memory controller to generate and issue commands to memory 930. The memory controller 922 can be a physical part of processor 910 or a physical part of interface 912. For example, memory controller 922 can be an integrated memory controller, integrated onto a circuit within processor 910.

System 900 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 900 includes interface 914, which can be coupled to interface 912. In one example, interface 914 represents an interface circuit, which can include standalone components and integrated circuitry. In one example, user interface components or peripheral components, or both, couple to interface 914. Network interface 950 provides system 900 the ability to communicate with remote devices (e.g., servers or other computing devices) over one or more networks. Network interface 950 can include an Ethernet adapter, wireless interconnection components, cellular network interconnection components, USB, or other wired or wireless standards-based or proprietary interfaces. Network interface 950 can transmit data to a device that is in the same data center or rack or a remote device, which can include sending data stored in memory.

Some examples of network interface 950 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include additional types of hardware interfaces, such as, for example, interfaces to semiconductor fabrication equipment and/or electrostatic charge management devices.

In one example, system 900 includes storage subsystem 980. Storage subsystem 980 includes storage device(s) 984, which can be or include any conventional medium for storing data in a nonvolatile manner, such as one or more magnetic, solid state, and/or optical based disks. Storage 984 can be generically considered to be a “memory,” although memory 930 is typically the executing or operating memory to provide instructions to processor 910. Whereas storage 984 is nonvolatile, memory 930 can include volatile memory (e.g., the value or state of the data is indeterminate if power is interrupted to system 900). In one example, storage subsystem 980 includes controller 982 to interface with storage 984. In one example controller 982 is a physical part of interface 912 or processor 910 or can include circuits or logic in both processor 910 and interface 914.

A power source (not depicted) provides power to the components of system 900. More specifically, power source typically interfaces to one or multiple power supplies in system 900 to provide power to the components of system 900.

Examples of systems may be implemented in various types of computing, smart phones, tablets, personal computers, and networking equipment, such as switches, routers, racks, and blade servers such as those employed in a data center and/or server farm environment.

### EXAMPLES

A method can comprise: selecting a multichip package assembly, wherein the multichip package assembly comprises a first die and a second die, wherein the first die comprises transmit circuitry and the second die comprises receive circuitry, wherein the transmit circuitry is electrically coupled to the receive circuitry, and wherein the receive circuitry comprises failing lane registers, injecting an error into a selected lane of the transmit circuitry, determining whether a failing lane register of the failing lane registers has correctly reported a failing lane. The error can be injected from a test controller in the first die. Determining whether includes comparing an output from a functional flop against a toggling pattern. Error injection can be performed serially multiple times for multiple lanes. Error injection can be performed in parallel on multiple lanes. The method can also include logging lane failures to user readable registers. The method can also include performing a repair for an identified failing lane.

A method can comprise: selecting a multichip package assembly, wherein the multichip package assembly comprises a first die and a second die, wherein the first die comprises first transmit circuitry and the second die comprises first receive circuitry, wherein the first die comprises a second transmit circuitry, wherein the second die comprises second receive circuitry; wherein the first transmit circuitry is electrically coupled to the first receive circuitry; rerouting a first signal path from the first transmit circuitry to the second transmit circuitry; and rerouting a second signal path from the second receive circuitry to the first receive circuitry. The second transmit circuitry can be redundant transmit circuitry. The second receive circuitry can be redundant receive circuitry. A failure can be identified in a signal lane that includes the first transmit circuitry and the first receive circuitry. The second transmit circuitry can comprise a first repair mux and the first signal path is routed through the first repair mux. The second receive circuitry can comprise a second repair mux and the second signal path is routed through the second repair mux. The second transmit circuitry can be electrically coupled to the second receive circuitry. The second transmit circuitry can be redundant transmit circuitry and wherein the second transmit circuitry is a proximate redundant transmit circuitry to the first transmit circuitry.

At least one machine-readable storage medium can comprise non-transitory instructions, that when executed by a processor, cause a device to: on a selected multichip package assembly, wherein the multichip package assembly comprises a first die and a second die, wherein the first die comprises first transmit circuitry and the second die comprises first receive circuitry, wherein the first die comprises a second transmit circuitry, wherein the second die comprises second receive circuitry, and wherein a first lane comprises the first transmit circuitry and the first receive circuitry, determine that the first lane comprises a fault; reroute a first signal path from the first transmit circuitry to the second transmit circuitry; and reroute a second signal path from the second receive circuitry to the first receive circuitry. The second transmit circuitry can be redundant transmit circuitry. The second receive circuitry can be redundant receive circuitry. The second transmit circuitry can comprise a first repair mux and the first signal path can be routed through the first repair mux. The second transmit circuitry can be redundant transmit circuitry wherein the second transmit circuitry is the closest redundant transmit circuitry to the first transmit circuitry.

Besides what is described herein, various modifications can be made to what is disclosed and implementations without departing from their scope. Therefore, the illustrations and examples herein should be construed in an illustrative, and not a restrictive sense.

What is claimed is:

1. A method comprising:
selecting a multichip package assembly, wherein the multichip package assembly comprises a first die and a second die, wherein the first die comprises transmit circuitry and the second die comprises receive circuitry, wherein the transmit circuitry is electrically coupled to the receive circuitry, and wherein the receive circuitry comprises failing lane registers,
injecting an error into a selected lane of the transmit circuitry, determining whether a failing lane register of the failing lane registers has correctly reported a failing lane.

2. The method of claim 1, wherein the error is injected from a test controller in the first die.

3. The method of claim 1 wherein determining whether includes comparing an output from a functional flop against a toggling pattern.

4. The method of claim 1 wherein error injection is performed serially multiple times for multiple lanes.

5. The method of claim 1 wherein error injection is performed in parallel on multiple lanes.

6. The method of claim 1 also including logging lane failures to user readable registers.

7. The method of claim 1 also including performing a repair for an identified failing lane.

8. A method comprising:
selecting a multichip package assembly, wherein the multichip package assembly comprises a first die and a second die, wherein the first die comprises first transmit circuitry and the second die comprises first receive circuitry, wherein the first die comprises a second transmit circuitry, wherein the second die comprises second receive circuitry; wherein the first transmit circuitry is electrically coupled to the first receive circuitry;
rerouting a first signal path from the first transmit circuitry to the second transmit circuitry; and
rerouting a second signal path from the second receive circuitry to the first receive circuitry.

9. The method of claim 8 wherein the second transmit circuitry is redundant transmit circuitry.

10. The method of claim 8 wherein the second receive circuitry is redundant receive circuitry.

11. The method of claim 8 wherein a failure has been identified in a signal lane that includes the first transmit circuitry and the first receive circuitry.

12. The method of claim 8 wherein the second transmit circuitry comprises a first repair mux and the first signal path is routed through the first repair mux.

13. The method of claim 8 wherein the second receive circuitry comprises a second repair mux and the second signal path is routed through the second repair mux.

14. The method of claim 8 wherein the second transmit circuitry is electrically coupled to the second receive circuitry.

15. The method of claim 8 wherein the second transmit circuitry is redundant transmit circuitry and wherein the second transmit circuitry is a proximate redundant transmit circuitry to the first transmit circuitry.

16. At least one machine-readable storage medium comprising non-transitory instructions, that when executed by a processor, cause a device to:
on a selected multichip package assembly, wherein the multichip package assembly comprises a first die and a second die, wherein the first die comprises first transmit circuitry and the second die comprises first receive circuitry, wherein the first die comprises a second transmit circuitry, wherein the second die comprises second receive circuitry, and wherein a first lane comprises the first transmit circuitry and the first receive circuitry, determine that the first lane comprises a fault;
reroute a first signal path from the first transmit circuitry to the second transmit circuitry; and
reroute a second signal path from the second receive circuitry to the first receive circuitry.

17. The at least one machine-readable storage medium of claim 16 wherein the second transmit circuitry is redundant transmit circuitry.

18. The at least one machine-readable storage medium of claim 16 wherein the second receive circuitry is redundant receive circuitry.

19. The at least one machine-readable storage medium of claim 16 wherein the second transmit circuitry comprises a first repair mux and the first signal path is routed through the first repair mux.

20. The at least one machine-readable storage medium of claim 16 wherein the second transmit circuitry is redundant transmit circuitry and wherein the second transmit circuitry is the closest redundant transmit circuitry to the first transmit circuitry.
